(19) United States
(12) Patent Application Publication
(10) Pub. No.: US 2019/0109026 A1
(43) Pub. Date: Apr. 11, 2019

(54) SEMICONDUCTOR PICK-UP APPARATUS

(71) Applicant: Mitsubishi Electric Corporation, Tokyo (JP)

(72) Inventors: Kinya YAMASHITA, Tokyo (JP); Masaki UENO, Tokyo (JP); Tatsuo HARADA, Tokyo (JP); Noritsugu NOMURA, Tokyo (JP)

(73) Assignee: Mitsubishi Electric Corporation, Tokyo (JP)

(21) Appl. No.: 16/055,218

(22) Filed: Aug. 6, 2018

(30) Foreign Application Priority Data
Oct. 11, 2017 (JP) 2017-197368

(51) Int. Cl. H01L 21/67; H01L 21/683

(52) U.S. Cl. CPC H01L 21/67132; H01L 2221/68322; H01L 21/6836

(57) ABSTRACT

Provided is a technique for detaching a semiconductor chip from a mount tape without failures in the semiconductor chip, such as cracking and chipping. A semiconductor pick-up apparatus includes the following components: a pick-up stage above which a semiconductor chip is to be placed through a mount tape attached to the lower surface of the semiconductor chip; an expander holding and expanding the mount tape; a push-up needle projecting from the upper surface of the pick-up stage, and capable of pushing up the semiconductor chip through the mount tape; and a mechanism pushing up the push-up needle while operating the push-up needle so as to form a spiral shape.

### BACKGROUND OF THE INVENTION

### Field of the Invention

The present invention relates to techniques of picking up diced semiconductor chips in process steps for manufacturing semiconductor devices, and particularly, to a technique of detaching such a semiconductor chip from a mount tape.

### Description of the Background Art

In power semiconductor elements, thinner wafers have been required in recent years in order to achieve higher efficiency along with improvements in device properties. Such a thin wafer lowers its strength, thus producing failures in the wafer, such as cracking and chipping, in wafer processing. Wafer processing needs to be improved, because this problem contributes to low manufacture yield and poor productivity.

The wafer that undergoes wafer processing to finally form a back-surface electrode and other components is temporarily attached to a mount tape so as to cut into semiconductor chip pieces. The wafer as attached to the mount tape has an arrangement of semiconductor chips coupled to each other. The wafer is cut into the semiconductor chip pieces with a blade or a laser while being attached to the mount tape. To pick up each semiconductor chip attached to the mount tape, the next step is hardening an adhesive contained in the mount tape after the dicing process through, for instance, UV irradiation, to thus reduce adhesion between the semiconductor chip and a dicing tape.

Then, the semiconductor chip is picked up from the mount tape. In a pick-up process of detaching the semiconductor chips from the mount tape, a common method is pushing up a needle from the back surface of the wafer through the mount tape, to thus separate the semiconductor chip from the mount tape. In this method, an external force locally applied at the time of semiconductor-chip detachment from the mount tape can cause various stresses to act on the semiconductor chip, thereby producing failures in the semiconductor chip, such as cracking and chipping.

In particular, a thin semiconductor chip, which has low strength, is quite likely to have such cracking and chipping When picked up.

Various pick-up apparatuses and various pick-up methods have been proposed in order to reduce cracking and chipping when such thin semiconductor chips are picked up. For instance, Japanese Patent Application Laid-Open No. 2003-264203 describes a technique of applying ultrasonic vibration to a needle that pushes up a semiconductor chip, to detach the semiconductor chip from a sheet using ultrasonic energy.

Japanese Patent Application Laid-Open No. 2007-158103 describes a technique of pushing up needles that push up a target semiconductor chip at different times from each other, to detach the target semiconductor chip from a sheet.

Japanese Patent Application Laid-Open No. 11-251408 describes a half-cut wafer dicing. In this technique, to separate adjacent semiconductor chips coupled to each other, the entire back surface of a wafer is uniformly scraped with needles through a mount tape on the back surface of the water.

Japanese Patent Application Laid-Open No. 2012-256931 describes a technique of forming steps of groove for mount-tape suction in the outer peripheral ends of a target semiconductor chip and semiconductor chips adjacent to the target semiconductor chip so as to detach the mount tape in the outer peripheral end of the target semiconductor chip.

In these conventional and typical methods for picking up the semiconductor chips and semiconductor chip pick-up apparatuses described in the aforementioned patent documents, in which the semiconductor chips are pushed up by the needles from below the lower surfaces of the mount tapes, local forces are applied to locations pushed up by the needles. Manufacture variation in cutting into the semiconductor chips, which are increasingly developed to be thinner, produces adhesion variation between the mount tapes. This can cause a great degree of deformation in the semiconductor chip, thereby involving cracking. In addition, a failure in mount tape detachment involves cracking.

### SUMMARY

It is an object of the present invention to provide a technique for detaching a semiconductor chip from a mount tape without failures in the semiconductor chip, such as cracking and chipping.

The present invention provides a semiconductor pick-up apparatus including a pick-up stage, an expander, a pusher, and a mechanism configured to push up the pusher while operating the pusher so as to form a spiral shape or a zigzag shape. A semiconductor chip is to be placed above the pick-up stage through a mount tape attached to the lower surface of the semiconductor chip. The expander holds and expands the mount tape. The pusher projects from the upper surface of the pick-up stage, and is capable of pushing up the semiconductor chip through the mount tape.

Such a configuration enables the pusher to be pushed up while operating the pusher from the outer peripheral portion of the semiconductor chip toward the inside. Consequently, the detachment between the semiconductor chip and the mount tape gradually proceeds, thereby preventing the failures in the semiconductor chip, such as cracking and chipping.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor pick-up apparatus according to a first preferred embodiment;

FIG. 2 is a perspective view of a pick-up stage;

FIG. 3 is a plan view of the pick-up stage;

FIG. 4 is a cross-sectional view of the pick-up stage;

FIG. 5 is a plan view of a pick-up stage having a whirl region of square (large size);

FIG. 6 is a plan view of a pick-up stage having a whirl region of square (small size);

FIG. 7 is a plan view of a pick-up stage having a whirl region of rectangle;

FIG. 8A is a plan view of a pick-up stage included in a semiconductor pick-up apparatus according to a second preferred embodiment;

FIG. 8B is a side view of the pick-up stage;

FIG. 8C is a diagram of four sections of the pick-up stage;

FIG. 9A is a plan view of the operation of push-up blocks in a step for picking up a semiconductor chip;

FIG. 9B is a side view of the operation of the push-up blocks;

FIG. 10A is a plan view of the operation of the push-up blocks in another step for picking up the semiconductor chip;

FIG. 10B is a side view of the operation of the push-up blocks;

FIG. 11A is a plan view of the operation of the push-up blocks in still another step for picking up the semiconductor chip;

FIG. 11B is a side view of the operation of the push-up blocks;

FIG. 12A is a plan view of the operation of the push-up blocks in yet another step for picking up the semiconductor chip;

FIG. 12B is a side view of the operation of the push-up blocks;

FIG. 13A is a plan view of the operation of the push-up blocks in further another step for picking up the semiconductor chip;

FIG. 13B is a side view of the operation of the push-up blocks;

FIG. 14A is a plan view of the operation of the push-up blocks in still yet another step for picking up the semiconductor chip;

FIG. 14B is a side view of the operation of the push-up blocks;

FIG. 15 is a perspective view of a pick-up stage included in a semiconductor pick-up apparatus according to a third preferred embodiment; and

FIG. 16 is a plan view of the pick-up stage.

### DESCRIPTION OF THE PREFERRED EMBODIMENTS

### First Preferred Embodiment

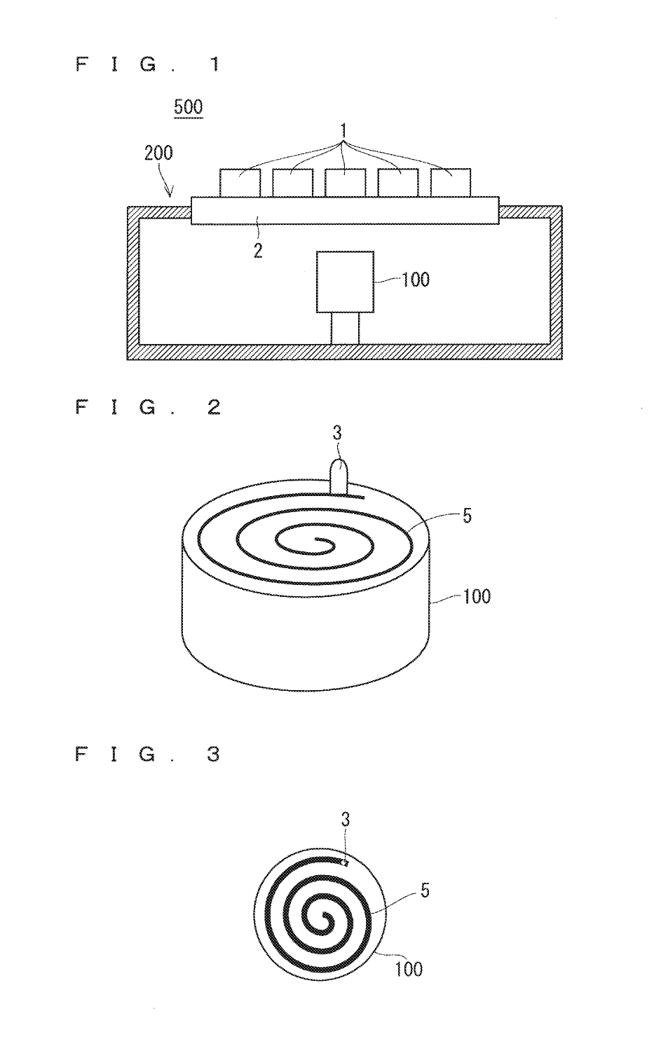

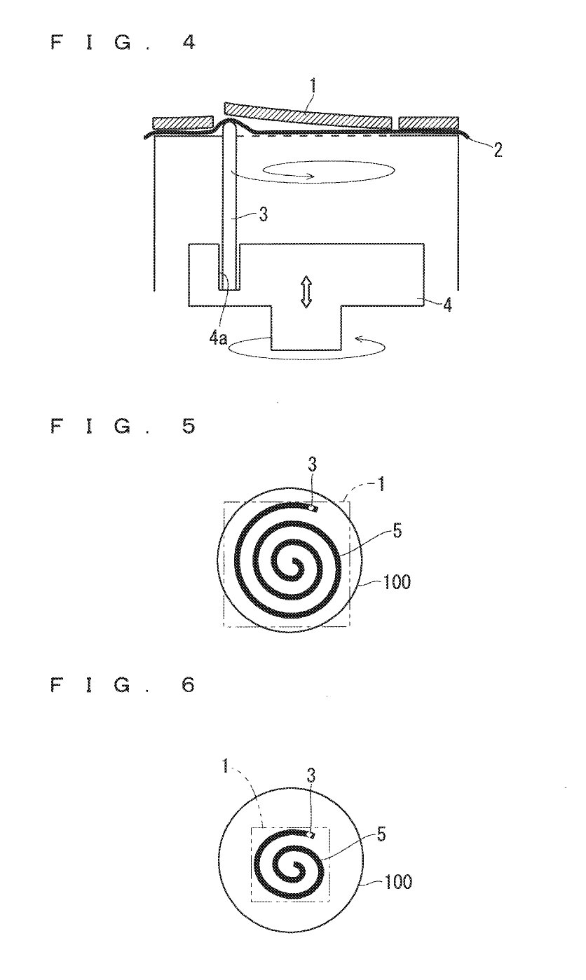

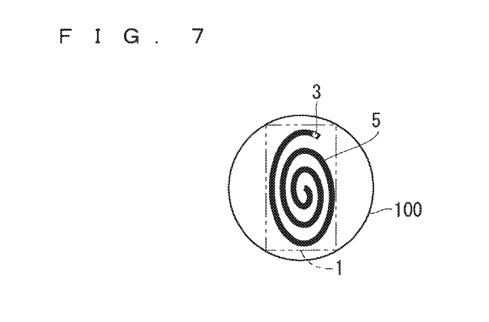

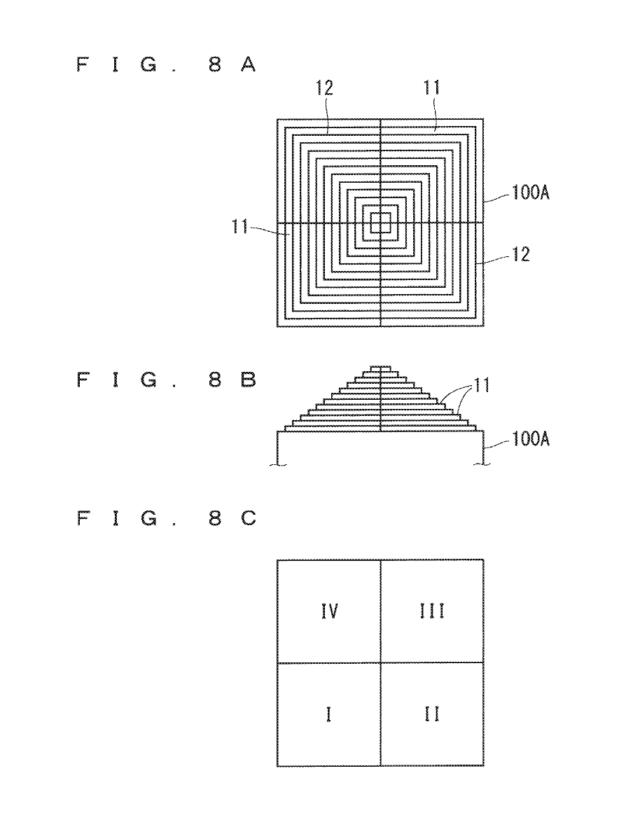

The following describes a first preferred embodiment with reference to the drawings. FIG. 1 is a cross-sectional view of a semiconductor pick-up apparatus 500 according to the first preferred embodiment. FIG. 2 is a perspective view of a pick-up stage 100. FIG. 3 is a plan view of the pick-up stage 100. FIG. 4 is a cross-sectional view of the pick-up stage 100. FIG. 5 is a plan view of the pick-up stage 100 having a whirl region of square (large sire). FIG. 6 is a plan view of the pick-up stage 100 having a whirl region of square (small size). FIG. 7 is a plan view of the pick-up stage 100 having a whirl region of rectangle.

First of all, a configuration of the semiconductor pick-up apparatus 500 will be described with reference to FIG. 1. The semiconductor pick-up apparatus 500 includes the pick-up stage 100 and an expander 200. The pick-up stage 100 is used to place at least one semiconductor chip 1 to be picked up at the center portion through a mount tape 2 attached to the lower surface of a plurality of semiconductor chips 1. The plurality of semiconductor chips 1 are formed by dicing a wafer attached to the mount tape 2 into separate pieces. The expander 200 is disposed above the pick-up stage 100. The expander 200 holds and expands the mount tape 2.

Configurations of the pick-up stage 100 and its surroundings will be next described. As illustrated in FIGS. 2 to 4, the semiconductor pick-up apparatus 500 further includes a pusher, which in this embodiment is a push-up needle 3, a push-up mechanism (not shown) including a needle holder 4, a hole 5 having a spiral shape, and a suction mechanism (not shown).

The pick-up stage 100 is substantially cylindrical in shape. The inside of the pick-up stage 100 is provided with the suction mechanism. Part of the needle holder 4 is disposed inside the pick-up stage 100. The push-up mechanism has an X-axis motor, a Y-axis motor, a Z-axis motor, and a θ-axis motor. The X-axis motor, the Y-axis motor, the Z-axis motor, and the θ-axis motor are driven to respectively move the needle holder 4 in an X-axis direction, a Y-axis direction, a Z-axis direction, and a θ-axis direction. It is noted that the X-axis direction is a side-to-side direction; the Y-axis direction, a front-to-back direction; the Z-axis direction, an up-and-down direction; and the θ-axis direction, a direction of rotation oriented to the Z-axis direction.

The push-up needle 3 has a proximal end portion (i.e., other end portion) fixed to a needle-holding cavity 4a of the needle holder 4 disposed inside the pick-up stage 100. The push-up needle 3 has a distal end portion one end portion) projectable from the spiral hole 5 disposed on the upper surface of the pick-up stage 100, and pushes up the lower surface of the semiconductor chip 1 through the mount tape 2. It is noted that the spiral shape is herein a curve moving away from the center along with whirl.

The needle holder 4 is controlled by a controller (not shown) included in the semiconductor pick-up apparatus 500 so as to operate in an up-and-down direction and in a spiral manner. More specifically, the needle holder 4 is operated in an up-and-down direction and in a spiral manner by the drive of the X-axis, Y-axis, Z-axis, and θ-axis motors. When the needle holder 4 moves upward, the needle 3 projects upward along the hole 5 from the upper surface of the pick-up stage 100.

The hole 5 is disposed on the upper surface of the pick-up stage 100 in a spiral form. The push-up needle 3 has an operational range whose maximum falls within the range of the upper surface of the pick-up stage 100. The operational range of the push-up needle 3 is selectable according to sizes of the semiconductor chip 1. The hole 5 has a corner-removed portion formed through corner removal. More specifically, the edge portion of the hole 5 undergoes corner removal. Examples of corner removal include filleting and chamfering. The push-up needle 3 has a variable push-up degree. The push-up needle 3 is operable along with a gradual increase in push-up degree.

The push-up needle 3 is operable along the spiral hole 5. More specifically, the push-up needle 3 operates in a direction oriented from an outermost peripheral portion that is a one-end side of the spiral hole 5, toward an innermost peripheral portion that is an other-end side of the spiral hole 5.

The tip of the push-up needle 3 is spherical or plane in shape. The tip, when having a plane shape, undergoes corner removal at its edge portion. Examples of corner removal include filleting and chamfering. The tip, when having a sphere shape, has not just a radius, but a considerably large radius with respect to the diameter of the push-up needle 3. This eliminates a deformation of the semiconductor chip 1. The push-up needle 3 is made of metal. This makes the push-up needle 3 resistant to wearing out, thereby enhancing its lifetime. Alternatively, the push-up needle 3 is made of resin, which is inexpensive. This saves manufacture costs.

Preparing several kinds of pick-up stage 100 in conformance with sizes and aspect ratios of the semiconductor chip 1 achieves several types of hole 5 having shareable sizes and shareable shapes. For a semiconductor chip 1 having a square shape (large size), the hole 5 has a shape illustrated in FIG. 5; for a semiconductor chip 1 having a square shape (small size), a shape illustrated in FIG. 6; and for a semiconductor chip 1 having a rectangular shape, a shape illustrated in FIG. 7. Further, changing the starting point of push-up of the push-up needle 3 achieves a shape shareable between FIGS. 5 and 6.

The hole 5 is connected to the suction mechanism disposed inside the pick-up stage 100. Switching suction operation in the suction mechanism between ON and OFF enables the suction and release of the semiconductor chip 1 through the mount tape 2.

The following describes the operation of the semiconductor pick-up apparatus 500. The push-up needle 3 operates in a direction oriented from the outermost peripheral portion of the spiral hole 5 toward the innermost peripheral portion of the spiral hole 5 with the semiconductor chip 1 being sucked to the upper surface of the pick-up stage 100 through the mount tape 2. As illustrated in FIG. 4, the semiconductor chip 1 is pushed up through the mount tape 2 as sucked, thus producing a detachment starting point on the mount tape 2 from an outermost peripheral portion of the semiconductor chip 1 to gradually start the detachment. The detachment between the semiconductor chip 1 and the mount tape 2 proceeds as the push-up needle 3 moves toward the center portion of the upper surface of the pick-up stage 100.

As described above, the semiconductor pick-up apparatus 500 according to the first preferred embodiment includes the following components: the pick-up stage 100 above which the semiconductor chip 1 is to be placed through the mount tape 2 attached to the lower surface of the semiconductor chip 1; the expander 200 holding and expanding the mount tape 2; the push-up needle 3 projecting from the upper surface of the pick-up stage 100, and capable of pushing up the semiconductor chip 1 through the mount tape 2; and the mechanism pushing up the push-up needle 3 while operating the push-up needle 3 so as to form a spiral shape.

Such a configuration enables the push-up needle 3 to be pushed up while operating the push-up needle 3 from the outer peripheral portion of the semiconductor chip 1 toward the inside. Consequently, the detachment between the semiconductor chip 1 and the mount tape 2 gradually proceeds, thereby preventing failures in the semiconductor chip 1, such as cracking and chipping.

The push-up needle 3 has an operational range whose maximum falls within the range of the upper surface of the pick-up stage 100. The operational range of the push-up needle 3 is selectable by changing the size of the upper surface of the pick-up stage 100 in conformance with sizes and aspect ratios of the semiconductor chip 1. Accordingly, preparing several kinds of pick-up stage 100 achieves several types of hole 5 having shareable sizes and shareable shapes.

The push-up needle 3 has a variable operational speed. For a high-adhesion mount tape 2, pushing up the push-up needle 3 slowly further prevents the failures in the semiconductor chip 1, such as cracking and chipping. For a low-adhesion mount tape 2, pushing up the push-up needle 3 quickly saves time for process steps.

The push-up needle 3 has a variable push-up degree. For a high-adhesion mount tape 2, increasing the degree of push-up further prevents the failures in the semiconductor chip 1, such as cracking and chipping. For a low-adhesion mount tape 2, reducing the degree of push-up further prevents the failures in the semiconductor chip 1, such as cracking and chipping.

In the preferred embodiment, the push-up needle 3 operates in a direction oriented from the one-end side of the spiral shape toward the other-end side of the same. The push-up needle 3 may operate in any other direction. For instance, the push-up needle 3 can operate in a direction oriented from the one-end side of the spiral shape toward the other-end side of the same, and then upon reaching the other-end side, operate in a direction oriented from the other-end side toward the one-end side. Such a repeated operation in the push-up needle 3 helps the detachment between the semiconductor chip 1 and the mount tape 2. Consequently, the push-up needle 3 is operable while having a small degree of push-up. As a result, the push-up needle 3 is operable both when the mount tape 2 has high adhesion and when the mount tape 2 has low adhesion.

A high-adhesion mount tape 2 can produce failures in the semiconductor chip 1, such as cracking and chipping, in the middle of the operation of the push-up needle 3. The push-up needle 3, which operates along with a gradual increase in push-up degree, reduces a pressure on the semiconductor chip 1, thereby further preventing the failures in the semiconductor chip 1, such as cracking and chipping.

The semiconductor pick-up apparatus 500 further includes the spiral hole 5 disposed on the upper surface of the pick-up stage 100, and the mechanism sucking the mount tape 2 through the hole 5. The push-up needle 3 operates along the hole 5. The mechanism, sucking the mount tape 2, has a variable suction force. Such a configuration prevents the semiconductor chip 1 from being sucked with an excessively large force, thereby further preventing the failures in the semiconductor chip 1, such as cracking and chipping.

The hole 5 has a corner-removed portion formed through filleting or chamfering. Thus, the edge portion of the hole 5 is removed. This reduces pressure locally applied to the semiconductor chip 1, thereby further preventing the failures in the semiconductor chip 1, such as cracking and chipping.

The push-up needle 3, which is made of metal, is resistant to wearing out, thereby enhancing its lifetime. Such a configuration also prevents the failures in the semiconductor chip 1, such as cracking and chipping, resulting from changes in shape of the push-up needle 3.

The push-up needle 3 is made of resin, which is inexpensive. This saves the manufacture costs.

The push-up needle 3 has a tip having a sphere shape or a plane shape. The tip has an edge portion provided with a corner-removed portion formed through filleting or chamfering. Removing the edge portion of the push-up needle 3 reduces a force locally applied to the semiconductor chip 1, thereby further preventing the failures in the semiconductor chip 1, such as cracking and chipping.

### Second Preferred Embodiment

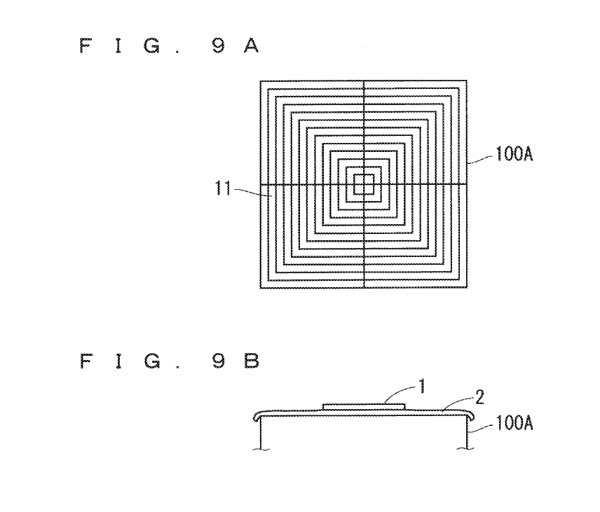

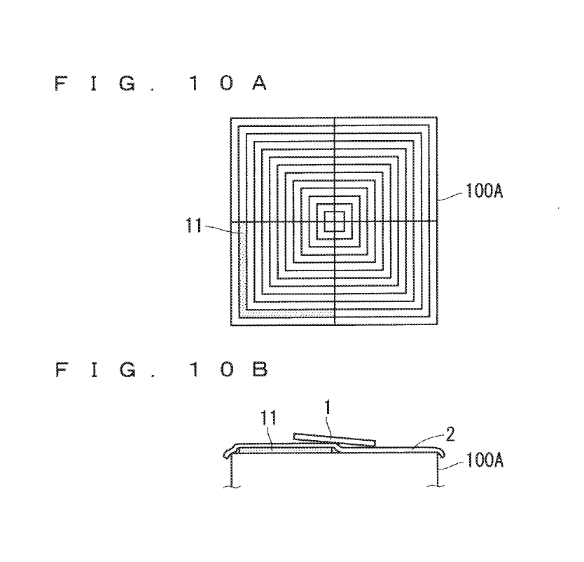

The following describes a pick-up stage 100A and its surroundings that are included in a semiconductor pick-up apparatus according to a second preferred embodiment. FIG. 8A is a plan view of the pick-up stage 100A in the semiconductor pick-up apparatus according to the second preferred embodiment. FIG. 8B is a side view of the pick-up stage 100A. FIG. 8C is a diagram of four sections of the pick-up stage 100A. FIGS. 9A, 10A, 11A, 12A, 13A, and 14A are plan views of the operation of push-up blocks 11 in individual steps for picking up a semiconductor chip 1. FIGS. 9B, 10B, 11B, 12B, 13B, and 14B are side views of the operation of the push-up blocks 11. It is noted that the same components between the first and second preferred embodiments are denoted by the same symbols, and thus will not be elaborated upon here.

As illustrated in FIGS. 8A and 8B, the pick-up stage 100A has a rectangular cylinder shape and is provided with a plurality of pushers, which in the second preferred embodiment is a plurality of push-up blocks 11.

The push-up blocks 11 each have an L-shape in plan view. As illustrated in FIGS. 8A and 8C, the pick-up stage 100A is divided into four sections, I to IV, and in each section, a predetermined number of L-shaped push-up blocks 11 are horizontally arranged. The tips of the plurality or push-up blocks 11 constitute the upper surface of the pick-up stage 100A. As such, the semiconductor chip 1 is placed at the tips of the plurality of push-up blocks 11 through a mount tape 2. Each push-up block 11 has an operational range whose maximum falls within the range of the upper surface of the pick-up stage 100A.

Some of the push-up blocks 11 that are closer to the outer periphery of the pick-up stage 100A have longer lengths of L-shape. Other push-up blocks 11 that are closer to the inner periphery of the pick-up stage 100A have shorter lengths of L-shape. Each push-up block 11 is configured such that its upward and downward movements are separately controlled by a push-up mechanism. The push-up blocks 11 have a variable push-up degree. Some of the push-up blocks 11 that are closer to the inner periphery of the pick-up stage 100A have greater push-up degrees. Further, the push-up blocks 11 have a variable operational speed.

Inlets 12 are disposed between the pick-up stage 100A and the push-up blocks 11 located in the outermost periphery, and between the push-up blocks 11 and the push-up blocks 11 adjacent thereto. The inlets 12 are connected to a suction mechanism.

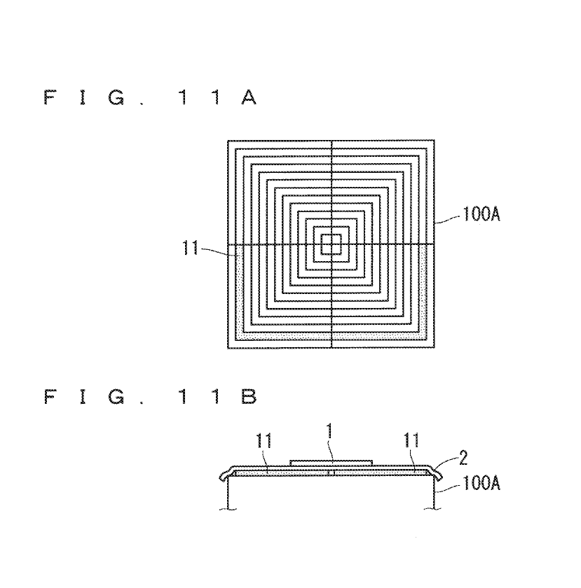

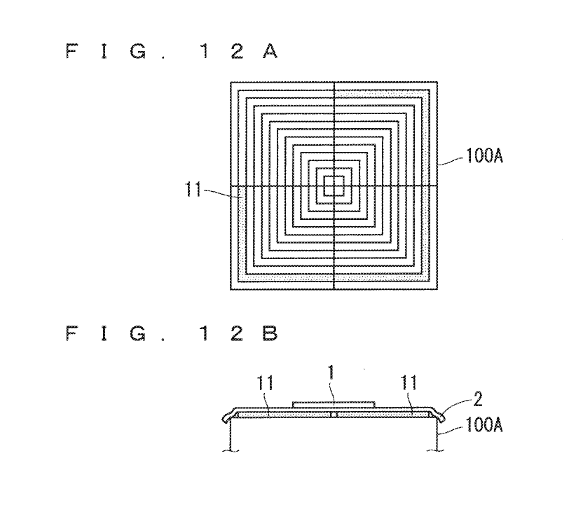

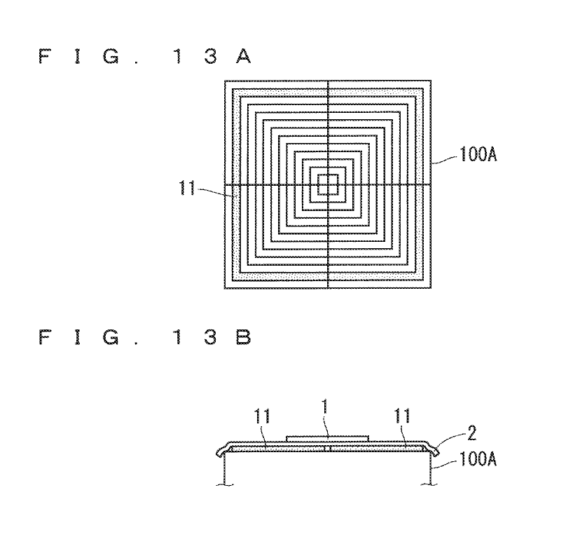

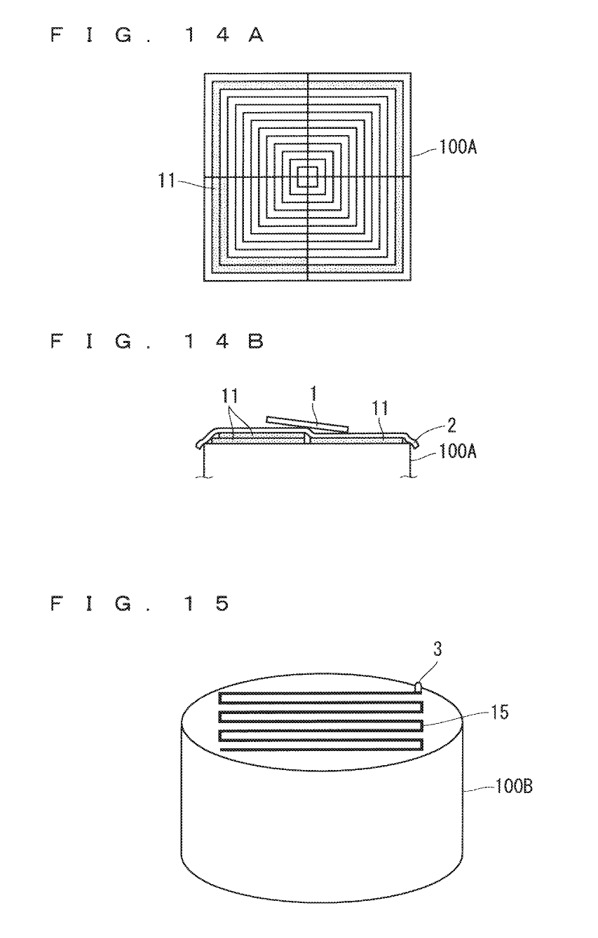

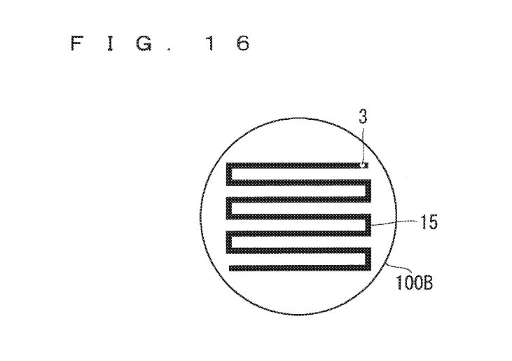

The following describes the operation of the semiconductor pick-up apparatus. The push-up mechanism operates the plurality of push-up blocks 11 so as to form a spiral shape with the semiconductor chip 1 being sucked to the tips of the push-up blocks 11 through the mount tape 2. More specifically, as illustrated in FIGS. 9A through 14B, the push-up mechanism operates the outermost push-up blocks 11 in sequence, followed by, one-by-one, the inner push-up blocks 11 in the four sections, I to IV. In one example, the push-up mechanism can operate each push-up block in the following order: the outermost push-up block 11 in section I (c.f., FIGS. 10A and 10B), the outermost push-up block 11 in section II (c.f., FIGS. 11A and 11B), the outermost push-up block 11 in section III (c.f., FIGS. 12A and 12B), the outermost push-up block 11 in section IV (c.f., FIGS. 13A and 13B), and the second outermost push-up block 11 in section I (c.f., FIGS. 14A and 14B).

In another example, the push-up mechanism can simultaneously operate, pair-by-pair, pairs of two push-up blocks 11 located in the respective sections on diagonal lines, e.g., a single push-up block 11 in section I and a single push-up block 11 in section III in a pair, and a single push-up block 11 in section II and a single push-up block 11 in section IV in a pair. Alternatively, the push-up mechanism can simultaneously operate, group by group, groups of four push-up blocks 11 located in the respective four sections. Chip push-up needs to start from the end portion of the semiconductor chip 1. For a semiconductor chip 1 having a shorter side of 1 mm or greater, the lengths of the L-shaped push-up blocks 11 are changeable according to sizes of the semiconductor chip 1.

As described above, the semiconductor pick-up apparatus according to the second preferred embodiment includes the plurality of push-up blocks 11. Pushing up the semiconductor chip 1 using the push-up blocks 11 prevents the semiconductor chip 1 from tilt. This prevents a target semiconductor chip 1 as pushed up from being in contact with a different semiconductor chip 1 adjacent to the target semiconductor chip 1. In addition, such push-up produces a plurality of starting points of detachment between the semiconductor chip 1 and the mount tape 2. This prevents failures in the semiconductor chip 1, such as cracking and chipping.

### Third Preferred Embodiment

The following describes a pick-up stage 100B and its surroundings that are included in a semiconductor pick-up apparatus according to a third preferred embodiment. FIG. 15 is a perspective view of the pick-up stage 100B in the semiconductor pick-up apparatus according to the third preferred embodiment. FIG. 16 is a plan view of the pick-up stage 100B. It is noted that the same components between the third preferred embodiment, and the first and second preferred embodiments are denoted by the same symbols, and thus will not be elaborated upon here.

The first preferred embodiment describes the hole 5 having a spiral shape. As illustrated in FIGS. 15 and 16, the third preferred embodiment describes a hole 15 disposed on the upper surface of the pick-up stage 100B and having a zigzag shape. Like the pick-up stage 100, the pick-up stage 100B is substantially cylindrical in shape. The pick-up stage 100B has no lower surface and is thus open at its lower part. It is noted that the zigzag shape herein means a shape formed by bending a straight line in left and right directions several times. The operation of a push-up needle 3 along the zigzag hole 15 enables push-up from an end portion on one side of the semiconductor chip 1 to an end portion on the opposite side in conformance with sizes of the semiconductor chip 1.

The hole 15 has a corner-removed portion formed through corner removal. More specifically, the edge portion of the hole 5 undergoes corner removal. Examples of corner removal include filleting and chamfering. The push-up needle 3 has a variable push-up degree.

Like the hole in the first preferred embodiment, preparing several kinds of pick-up stage 100 in conformance with sizes and aspect ratios of the semiconductor chip 1 achieves several types of hole 15 having shareable sizes and shareable shapes.

The following describes the operation of the semiconductor pick-up apparatus according to the third preferred embodiment. The push-up needle 3 operates in a direction oriented from one end portion of the zigzag hole 15 toward the other end portion of the zigzag hole 15 with the semiconductor chip 1 being sucked to the pick-up stage 100B through a mount tape 2. As illustrated in FIG. 4, the semiconductor chip 1 is pushed up through the mount tape 2 as sucked, thus producing a starting point of detachment of the mount tape 2 from the outermost peripheral portion of the semiconductor chip 1 to gradually start the detachment. The detachment between the semiconductor chip 1 and the mount tape 2 proceeds as the push-up needle 3 moves toward the other end portion of the hole 15.

As described above, the semiconductor pick-up apparatus according to the third preferred embodiment includes the following components: the pick-up stage 100B above which the semiconductor chip 1 is to be placed through the mount tape 2 attached to the lower surface of the semiconductor chip 1; an expander 200 holding and expanding the mount tape 2; the push-up needle 3 projecting from the upper surface of the pick-up stage 100B, and capable of pushing up the semiconductor chip 1 through the mount tape 2; and a mechanism pushing up the push-up needle 3 while operating the push-up needle 3 so as to form a zigzag shape.

Such a configuration enables the push-up needle 3 to be pushed up while operating the push-up needle 3 from the outer peripheral portion of the semiconductor chip 1 toward the inside. Consequently, the detachment between the semiconductor chip 1 and the mount tape 2 gradually proceeds, thereby preventing failures in the semiconductor chip 1, such as cracking and chipping.

In the preferred embodiment, the push-up needle 3 operates in a direction oriented from a one-end side of the zigzag hole 15 toward an other-end side of the same. The push-up needle 3 may operate in any other direction. For instance, the push-up needle 3 can operate in a direction oriented from the one-end side of the zigzag hole 15 toward the other-end side of the same, and upon reaching the other-end side, operate in a direction oriented from the other-end side toward the one-end side. Such a repeated operation in the push-up needle 3 helps the detachment between the semiconductor chip 1 and the mount tape 2. Consequently, the push-up needle 3 is operable while having a small degree of push-up. As a result, the push-up needle 3 is operable both when the mount tape 2 has high adhesion and when the mount tape 2 has low adhesion.

The semiconductor pick-up apparatus further includes the hole 15 disposed on the upper surface of the pick-up stage 100B and having a zigzag shape and, and a mechanism sucking the mount tape 2 through the hole 15. The push-up needle 3 operates along the hole 15. The mechanism, sucking the mount tape 2, has a variable suction force. Such a configuration prevents the semiconductor chip 1 from being sucked with an excessively large force, thereby further preventing the failures in the semiconductor chip 1, such as cracking and chipping.

The hole 15 has a corner-removed portion formed through filleting or chamfering. Thus, the edge portion of the hole 5 is removed. This reduces pressure locally applied to the semiconductor chip 1, thereby further preventing the failures in the semiconductor chip 1, such as cracking and chipping.

It is noted that in the present invention, the individual embodiments can be freely combined, or can be modified and omitted as appropriate, within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor pick-up apparatus comprising:
a pick-up stage above which a semiconductor chip is to be placed through a mount tape attached to a lower surface of the semiconductor chip;
an expander holding and expanding the mount tape;
at least one pusher projecting from an upper surface of the pick-up stage, and capable of pushing up the semiconductor chip through the mount tape; and
a mechanism configured to push up the pusher while operating the pusher so as to form a spiral shape or a zigzag shape.

2. The semiconductor pick-up apparatus according to claim 1, wherein the pusher has an operational range whose maximum falls within a range of the upper surface of the pick-up stage.

3. The semiconductor pick-up apparatus according to claim 1, wherein the pusher has a variable operational speed.

4. The semiconductor pick-up apparatus according to claim 1, wherein the pusher has a variable push-up degree.

5. The semiconductor pick-up apparatus according to claim 1, wherein the pusher is configured to operate in a direction oriented from a one-end side of the spiral shape or the zigzag shape toward an other-end side of the spiral shape or the zigzag shape, and upon reaching the other-end side, operate in a direction oriented from the other-end side toward the one-end side.

6. The semiconductor pick-up apparatus according to claim 1, wherein the at least one pusher comprises a plurality of pushers.

7. The semiconductor pick-up apparatus according to claim 1, wherein the pusher is configured to operate along with a gradual increase in push-up degree.

8. The semiconductor pick-up apparatus according to claim 1, further comprising:
a hole disposed on the upper surface of the pick-up stage, and having the spiral shape or the zigzag shape; and
a mechanism configured to suck the mount tape through the hole,
wherein the pusher is configured to operate along the hole, and
the mechanism configured to suck the mount tape has a variable suction force.

9. The semiconductor pick-up apparatus according to claim 8, wherein the hole comprises a corner-removed portion formed through filleting or chamfering.

10. The semiconductor pick-up apparatus according to claim 1, wherein the pusher is made of metal.

11. The semiconductor pick-up apparatus according to claim 1, wherein the pusher is made of resin.

12. The semiconductor pick-up apparatus according to claim 10, wherein
the pusher comprises a tip having a sphere shape or a plane shape, and
the tip comprises an edge portion comprising a corner-removed portion formed through filleting or chamfering.

13. The semiconductor pick-up apparatus according to claim 11, wherein
the pusher comprises a tip having a sphere shape or a plane shape, and
the tip comprises an edge portion comprising a corner-removed portion formed through filleting or chamfering.
